(19) United States
(12) Patent Application Publication
(10) Pub. No.: US 2020/0013983 A1
(43) Pub. Date: Jan. 9, 2020

(54) ORGANIC LIGHT-EMITTING DIODE WITH OUTPUT OPTIMISED BY CONFINEMENT OF PLASMONS AND DISPLAY DEVICE COMPRISING A PLURALITY OF SUCH DIODES

(71) Applicant: COMMISSARIAT A L'ENERGIE ATOMIQUE ET AUX ENERGIES ALTERNATIVES, PARIS (FR)

(72) Inventors: Salim BOUTAMI, GRENOBLE (FR); Stéphane GETIN, GRENOBLE (FR); Tony MAINDRON, GRENOBLE (FR); Benoit RACINE, Bevenais (FR)

(21) Appl. No.: 16/491,139

(22) PCT Filed: Mar. 14, 2018
(86) PCT No.: PCT/EP2018/056452

§ 371 Date: Sep. 4, 2019

(30) Foreign Application Priority Data
Mar. 15, 2017 (FR) 1752095

(51) Int. Cl. H01L 51/52; H01L 51/00

(52) U.S. Cl. CPC H01L 51/5203; H01L 51/0017; H01L 51/5278; H01L 51/5275

(57) ABSTRACT

An organic light-emitting diode includes a first electrode, a stack of semiconductor organic layers comprising at least one electroluminescent organic layer, the stack being deposited above the first electrode, and a second electrode deposited on a surface of the stack, the surface being opposite the first electrode, wherein the first electrode comprises at least one region, making electrical contact with the stack of semiconductor organic layers, having a geometry suitable for allowing the excitation of a localized plasmon mode at the emission wavelength of the electroluminescent organic layer. Display device comprising a plurality of such diodes sharing a stack of semiconductor organic layers. Process for manufacturing such a diode and such a display device is also provided.

The invention relates to an organic light-emitting diode (OLED) and more particularly to a top-emitting OLED. Such a diode may be applied, in particular, to display applications (OLED displays) but also lends itself to other applications such as lighting.

The invention also relates to a display device, such as an OLED display, comprising a plurality of such diodes.

An OLED consists of a stack of semiconductor organic layers comprising at least one emitting layer, said stack being located between two electrodes, which are often made of metal. The organic stack consists of at least one hole-transport layer, an (electroluminescent) emission layer and an electron-transport layer. The thickness of the organic zone is generally set to about 100 nm, so as to form a half-wave Fabry-Pérot cavity for visible light (the refractive index of the organic layers is typically about 1.7). Applying a potential difference across the electrodes injects into the organic stack electrons and holes, which recombine radiatively in the emitting layer.

The emitters are at quite a small distance from the electrodes with respect to the wavelength, this causing plasmons to be excited on the surface of the electrodes, in addition to the useful radiative vertical Fabry-Pérot mode. These plasmons are planar-guided modes that are completely absorbed by the metal after a certain distance of lateral propagation.

Document WO 2014/191733 describes a top-emitting organic light-emitting diode (i.e. one that emits via the surface opposite the surface of the substrate), in which the top electrode, through which the light is emitted, is periodically structured so as to form a diffraction grating. Document US 2013/0153861 for its part describes a bottom-emitting, organic, light-emitting diode (i.e. one that emits through the substrate) in which it is the bottom electrode that is structured. Likewise, document WO 2014/069573 A1 describes a bottom-emitting, organic, light-emitting diode in which the bottom electrode comprises at least one region making electrical contact with the stack of organic layers, and the one or more regions making contact with the organic layers have a suitable geometry allowing the excitation of a plasmon mode at the emission wavelength. In these three cases, coupling to the grating allows—in a way known per se—the plasmons and the Fabry-Pérot modes to be extracted, thus improving the radiation efficiency.

This approach allows some of the energy of the plasmons to be extracted, but not does not completely eliminate the losses associated with the latter. Thus, the efficiency remains well below 50%. Furthermore, in the case of a top-emitting diode (WO 2014/191733), structuring the top electrode risks causing deterioration of the organic stack.

The invention aims to overcome the drawbacks of the prior art. More particularly, it aims to provide an organic light-emitting diode, in particular a top-emitting, organic, light-emitting diode, having a radiation efficiency higher than was possible in the prior art.

According to the invention, this aim is achieved using a thinned organic stack incapable of supporting Fabry-Pérot modes at its emission wavelengths, and a bottom electrode structured in the form of conductive pads of appropriate dimensions. The conductive pads form, with the continuous top electrode, resonators for the plasmons. Thus, instead of having plasmons that propagate over the surface of an unstructured electrode until being completely absorbed, localized plasmon modes (stationary waves) are generated that are diffracted by the edges of the pads and couple with the radiated electromagnetic modes that propagate out of the OLED. It will be noted that the operating principle is fundamentally different from that of a conventional OLED comprising a Fabry-Pérot cavity, and that the plasmons, instead of being a source of losses, are the origin of the light emission. This is made possible by the fact that it is a question of localized plasmons, which do not propagate as in the prior art.

An OLED according to the present invention has a narrower emission spectrum than the emission spectrum of a conventional diode comprising the same electroluminescent layer, the emission peak depending on the geometry of the conductive pads.

One subject of the invention is therefore an organic light-emitting diode comprising a first electrode, a stack of semiconductor organic layers comprising at least one electroluminescent organic layer, said stack being deposited above said first electrode, and a second electrode deposited on a surface of said stack, said surface being opposite said first electrode, the first and second electrode and the stack of semiconductor organic layers forming a Fabry-Pérot optical cavity, characterized in that said stack of semiconductor organic layers has an insufficient thickness to allow the existence of a Fabry-Pérot mode in said cavity at at least one emission wavelength of said electroluminescent organic layer, and in that said first electrode comprises at least one region making electrical contact with the stack of semiconductor organic layers, said region being encircled by one or several regions electrically insulated from said stack, said or each said region making electrical contact with the stack having a geometry suitable for allowing the excitation of a localized plasmon mode at said emission wavelength of said electroluminescent organic layer.

According to one particular embodiment of such an organic light-emitting diode, said or each said region of the first electrode making electrical contact with the stack of semiconductor organic layers may have at least one lateral dimension equal to

$$( 2 m + 1 ) \frac{λ}{2 {n}_{eff}} ,$$

where m is an integer higher than or equal to zero, λ is said wavelength and n_{eff} is an effective refractive index for plasmons localized between the electrodes in the stack of semiconductor organic layers. More particularly, said lateral dimension may be equal to

$$\frac{λ}{2 {n}_{eff}} .$$

Another subject of the invention is a process for manufacturing such an organic light-emitting diode, comprising:
a step of structuring a metal layer forming said first electrode by etching the one or more regions intended to be electrically insulated from said stack of semiconductor organic layers;
a step of depositing a dielectric layer above the structured first electrode;
a step of uncovering at least one unetched region of the first electrode, intended to make electrical contact with said stack of semiconductor organic layers; and
a step of depositing said stack of semiconductor organic layers above said first electrode, and of depositing the second electrode on a surface of said stack, said surface being opposite said first electrode.

Yet another subject of the invention is a display device comprising a matrix array of first electrodes, a stack of semiconductor organic layers comprising at least one electroluminescent organic layer, said stack being deposited above said first electrode, and a second electrode deposited on a surface of said stack, said surface being opposite said matrix array of first electrodes, each first electrode forming, with the second electrode and the stack of semiconductor organic layers, a Fabry-Pérot optical cavity, characterized in that:
said stack of semiconductor organic layers has an insufficient thickness to allow the existence of a Fabry-Pérot mode in said cavities in at least one part of the emission spectrum of said electroluminescent organic layer; and
said matrix array comprises a plurality of families of first electrodes, the first electrodes of a given family having geometries suitable for allowing the excitation of a localized plasmon mode at a given wavelength of said emission spectrum of said electroluminescent organic layer, said wavelength being different from that of the other families.

According to one particular embodiment of such a display device, said or each said first electrode may have at least one lateral dimension equal to

$$( 2 m + 1 ) \frac{λ}{2 {n}_{eff}} ,$$

where m is an integer higher than or equal to zero, λ is said wavelength and n_{eff} is an effective refractive index for plasmons localized between the electrodes in the stack of semiconductor organic layers. More particularly, said lateral dimension may be equal to

$$\frac{λ}{2 {n}_{eff}} .$$

Yet another subject of the invention is a process for manufacturing such a display device, comprising:
a step of structuring by etching a metal layer, defining unetched regions forming said first electrodes;
a step of depositing a dielectric layer above the structured metal layer;
a step of uncovering said first electrodes; and
a step of depositing said stack of semiconductor organic layers above said first electrodes, and of depositing the second electrode on a surface of said stack, said surface being opposite said first electrodes.

Other features, details and advantages of the invention will become apparent on reading the description given with reference to the appended drawings, which are given by way of example and show, respectively:

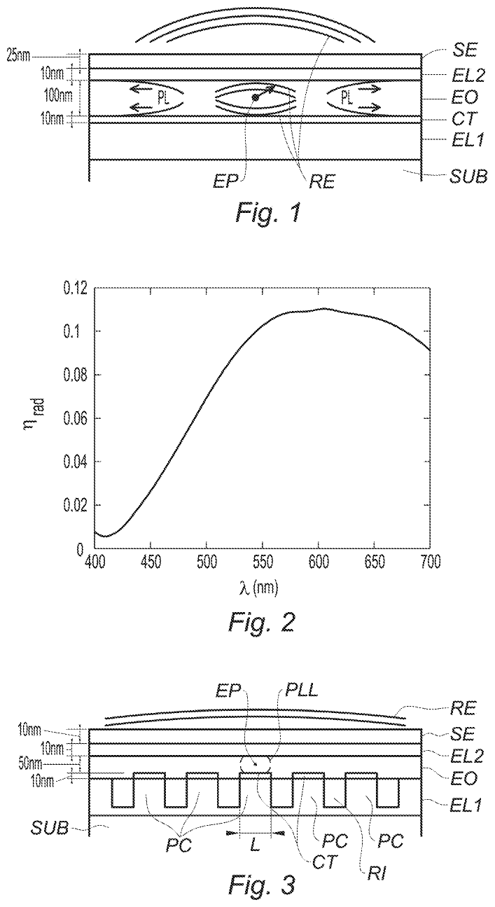

FIG. 1, an OLED according to the prior art;

FIG. 2, a graph of the radiation efficiency of the OLED in FIG. 1 as a function of emission wavelength;

FIG. 3, an OLED according to one embodiment of the invention;

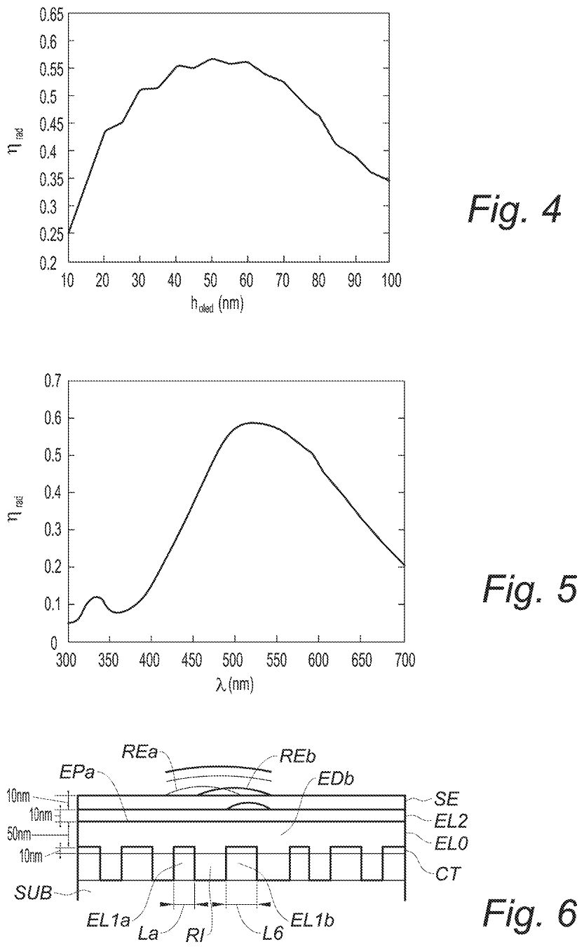

FIG. 4, a graph of the radiation efficiency of the OLED in FIG. 3 at the wavelength of 550 nm as a function of the thickness of its stack of semiconductor organic layers;

FIG. 5, a graph of the radiation efficiency of the OLED in FIG. 3 as a function of emission wavelength; and

FIG. 6, a display device according to another embodiment of the invention.

The organic light-emitting diode in FIG. 1 (which is not to scale) comprises, starting from the bottom:

A substrate SUB that may for example be made of glass or silicon.

A bottom electrode, made of AlCu alloy, deposited (for example by a physical vapor deposition or PVD) above a surface of the substrate. This electrode is opaque and may be relatively thick (several hundred nanometers, or even a few microns).

A buffer layer CT made of TiN, for example deposited by PVD, PECVD (plasma-enhanced chemical vapor deposition) or ALD (atomic layer deposition), having a thickness advantageously smaller than 10 nm in order to avoid excessive absorption and to decrease the amount of light reflected from the electrode EL1, typically about 5 nm.

An organic stack EO, for example deposited by wet processing or by PVD, of thickness typically comprised between 80 and 300 nm, for example 100 nm. At the center of this stack, there is an electroluminescent layer that has an emission centered on the wavelength of 550 nm. The figure does not show this layer, but only a point emitter (one point of the layer) EP. The reference RE has been used to reference the light radiation emitted by the point emitter, said radiation propagating in a direction substantially normal to the surface of the substrate. As was explained above, the thickness of the stack EO is chosen to be equal to λ/2n_{OLED}, where λ is a wavelength belonging to the emission spectrum of the electroluminescent layer (preferably the central wavelength, or the wavelength corresponding to the emissivity peak) and n_{OLED} is the average refractive index of the stack at this wavelength. In this way, the stack forms a Fabry-Pérot cavity for the emitted radiation.

The reference PL has been used to reference the plasmons guided by the interfaces between the organic stack and the top and bottom electrodes, which are sources of losses.

A top electrode EL2, deposited above the organic stack, made of Ag and having a thickness of 10 nm—sufficiently small to be substantially transparent.

An encapsulating structure SE covering the top electrode in order to protect the organic stack from atmospheric oxygen and more generally any contamination. In the device in FIG. 1, this encapsulating structure consists of a layer of SiOₓ (x≤2), manufactured for example by PVD, having a thickness of 25 nm. Other embodiments may comprise higher performance multilayer encapsulating structures. For example, it may be advantageous to provide, above the layer made of SiO₂, a second layer made of TiO₂ or Al₂O₃ produced by atomic layer deposition (ALD) and able to have a thickness as small as 5 nm. Such a very compact layer substantially improves the seal tightness of the encapsulation.

FIG. 2 is a graph of the radiation efficiency η_{rad} of the OLED in FIG. 1 as a function of the emission wavelength λ. The radiation efficiency in defined as the ratio between the radiated power P_{rad} and the sum of the same radiated power and the power absorbed P_{abs} by the metal electrodes:

$${η}_{rad} = \frac{{P}_{rad}}{{P}_{rad} + {P}_{abs}}$$

It may be seen that, even in the spectral region in which it is highest (550-600 nm), this efficiency barely exceeds 10%. This is largely due to the losses induced by the plasmons PL.

FIG. 3 shows a cross-sectional view of an OLED according to one embodiment of the invention. It differs from the OLED in FIG. 1 in two main ways:

The thickness of the organic stack EO has been decreased from 100 to 50 nm. This has two consequences: on the one hand, this thickness is insufficient to allow the existence of Fabry-Pérot modes in the visible spectrum, in which the emission of the electroluminescent layer is located; on the other hand, the top and bottom electrodes are close enough that their plasmon modes are highly coupled.

The lower electrode EL1 is structured into a set of conductive pads PC, which are separated by insulating regions—in practice cavities or trenches obtained by etching the electrode—and the buffer layer covering it—and filled with a dielectric material such as SiO₂ or a resist.

The geometry of the conductive pads PC is chosen in such a way that a localized plasmon mode PLL may be confined between a pad and the portion of top electrode EL2 directly opposite. In practice, the pads are often a circular-, square- or even polygonal-shaped; in this case, they must have a lateral dimension L (side length in the case of a square, diameter for a circle, distance between two opposite sides for a polygon, etc.) equal to half an uneven multiple of a wavelength λ of the emission spectrum of the electroluminescent layer, divided by an effective refractive index:

$$L = ( 2 m + 1 ) \frac{λ}{2 {n}_{eff}}$$

where m is an integer higher than or equal to 0. The effective index n_{eff} is higher than but close to the average index of the organic stack. The optimal configuration consists in the choice m=0. Specifically, it is diffraction by the edges of the pads that allows the localized plasmon modes to “escape” by coupling with the emitted radiative modes RE; increasing the order m, and therefore the size of the pad, merely increases the absorption of the localized plasmons, and therefore the losses.

Considering an effective index of about 1.7, the width of a pad optimized for an emission 550 nm is about 200 nm.

It is important to understand that the plasmon resonators formed by the pads are independent of one another. In other words, there is no grating effect: the separation between pads is not critical, provided that it is sufficient to prevent coupling between the plasmons localized in various pads; typically, it will be larger than or equal to 20% of the width of the pads. Thus, it is not necessary for the structure to be periodic, and at a stretch, the OLED can even comprise one single pad (though of course this implies a very concentrated light emission, from a very small area, and therefore a low total brightness).

The process for manufacturing the device in FIG. 3 is similar to that of a conventional OLED, except that it also comprises a step of structuring the bottom electrode and the deposition of a thinner organic layer.

The structuring is carried out in several steps. The first is an etch of the metal layer and of the buffer layer CT covering it. At the end of this etch, a thick layer of a dielectric, typically SiO₂, and which is sufficiently thick to fill the holes between the metal portions, is deposited. Lastly, in order to uncover the electrical contacts of the electrode EL1, a planarization, for example a chemical-mechanical planarization (CMP) is carried out. Next, the organic stack EO is deposited in a conventional way (while taking care to ensure that it has the sought-after thickness, which is much smaller than in the prior art), as are the second electrode and the encapsulating structure.

FIG. 4 is a graph of the radiation efficiency at λ=550 nm of an OLED according to the invention as a function of the thickness h_{oled} of the organic stack EO, i.e. of the distance between the electrodes. The calculations were carried out with the width of the pads set to L=200 nm. It may be seen that the efficiency is maximum for h_{oled}=50 nm, where it reaches 55%—higher by a factor of almost 5 than the case of the conventional OLED in FIG. 1—and varies very little between 40 and 60 nm.

FIG. 5 is a graph of the radiation efficiency at λ=550 nm of an OLED according to the invention as a function of the wavelength λ. The calculations were carried out with the width of the pads set to L=200 nm and with an inter-electrode distance of h_{oled}=50 nm. Comparison with FIG. 2 allows it to be observed that the improvement in the radiation efficiency occurs mainly about the wavelength used to dimension the pads (550 nm). Thus, the emission spectrum is narrower than in the prior art.

This narrowing of the emission spectrum is advantageous in certain applications, in particular in display applications. Specifically, it is possible to produce a device comprising a plurality of individual pad-shaped bottom electrodes that are individually controlled and that have different dimensions so as to obtain emission spectra centered on different wavelengths. In the embodiment of FIG. 6, the device comprises a matrix array of bottom electrodes belonging to two families: the electrodes EL1a have a first lateral dimension La, and are suitable for allowing the emission of a first emission REa; the electrodes Elb have a second lateral dimension Lb larger than La, and are suitable for allowing the emission of a second emission REb of a central wavelength longer than the wavelength of REa. These electrodes are deposited on the same substrate SUB and separated by insulating regions RI; they are covered with a common organic stack EO (the references EPa and EPb have been used to reference point emitters in the interior of this stack), with a common top electrode EL2 and with an encapsulating layer, as the OLED in FIG. 3. In practice, display devices comprising regular arrangements of lower electrodes of three or more different families will be used as a preference. For example, electrodes optimized to emit radiation in which the red, green and blue respectively dominate will possibly be used to produce a RGB screen display in which each individual electrode corresponds to one sub-pixel. The colors obtained according to the invention are insufficiently saturated to allow recourse to color filtering of the sub-pixels to be avoided; however, the invention allows the constraints on this filtering to be relaxed and/or the rendering of the colors to be improved.

The invention has been described mainly with reference to the embodiments of FIGS. 3 and 6, but many variants are possible.

The organic stack, the second electrode and the encapsulating structure are conventional elements and may be modified in a known manner.

The lower electrode generally serves as cathode and the upper electrode is anode, but the opposite is also possible.

The thicknesses of the various layers are not critical, provided that the organic stack is sufficiently thin.

The conductive pads may have more complex shapes than those considered up to now, for example shapes that cannot be characterized simply by a lateral dimension. What counts is that they are able to support a localized plasmon mode at at least one emission wavelength of the electroluminescent layer of the OLED.

1. An organic light-emitting diode comprising a first electrode (EL1), a stack (EO) of semiconductor organic layers comprising at least one electroluminescent organic layer, said stack being deposited above said first electrode, and a second electrode (EL2) deposited on a surface of said stack, said surface being opposite said first electrode, wherein said stack of semiconductor organic layers has an insufficient thickness to allow the existence of a Fabry-Pérot mode between the first and second electrode at at least one emission wavelength of said electroluminescent organic layer, and in that said first electrode comprises at least one region (PC) making electrical contact with the stack of semiconductor organic layers, said region being encircled by one or more regions electrically insulated (RI) from said stack, said or each said region making electrical contact with the stack having at least one lateral dimension equal to
$$( 2 m + 1 ) \frac{λ}{2 {n}_{eff}} ,$$
where m is an integer higher than or equal to zero, λ is said wavelength and n_{eff} is an effective refractive index for plasmons localized between the electrodes in the stack of semiconductor organic layers, so as to allow the excitation of a localized plasmon mode (PLL) at said emission wavelength of said electroluminescent organic layer.

2. The organic light-emitting diode as claimed in claim 1, wherein said lateral dimension is equal to
$$\frac{λ}{2 {n}_{eff}} .$$

3. The organic light-emitting diode as claimed in claim 1, wherein the thickness of the stack of the organic layers is smaller than 100 nm and preferably comprised between 20 and 85 nm and even preferably between 30 and 70 nm.

4. A display device comprising a matrix array (MEL) of first electrodes (EL1a, EL1b), a stack of semiconductor organic layers (EO) comprising at least one electroluminescent organic layer, said stack being deposited above said first electrode, and a second electrode (EL2) deposited on a surface of said stack, said surface being opposite said matrix array of first electrodes, each first electrode forming, with the second electrode and the stack of semiconductor organic layers, a Fabry-Pérot optical cavity, wherein:
said stack of semiconductor organic layers has an insufficient thickness to allow the existence of a Fabry-Pérot mode in said cavities in at least one part of the emission spectrum of said electroluminescent organic layer; and
said matrix array comprises a plurality of families of first electrodes, the first electrodes of a given family having at least one lateral dimension equal to
$$( 2 m + 1 ) \frac{λ}{2 {n}_{eff}} ,$$
where m is an integer higher than or equal to zero, λ is said wavelength and n_{eff} is an effective refractive index for plasmons localized between the electrodes in the stack of semiconductor organic layers, so as to allow the excitation of a localized plasmon mode (PLL) at said emission wavelength of said electroluminescent organic layer.

5. The display device as claimed in claim 1, wherein said lateral dimension is equal to
$$\frac{λ}{2 {n}_{eff}} .$$

6. A process for manufacturing an organic light-emitting diode as claimed in claim 1, comprising:
a step of structuring a metal layer forming said first electrode (EL1) by etching the one or more regions intended to be electrically insulated from said stack of semiconductor organic layers;
a step of depositing a dielectric layer (CD) above the structured first electrode;
a step of uncovering at least one unetched region (PC) of the first electrode, intended to make electrical contact with said stack of semiconductor organic layers; and
a step of depositing said stack (EO) of semiconductor organic layers above said first electrode, and of depositing the second electrode (EL2) on a surface of said stack, said surface being opposite said first electrode.

7. A process for manufacturing a display device as claimed in claim 4, comprising:
a step of structuring by etching a metal layer, defining unetched regions forming said first electrodes (EL1a, EL1b);
a step of depositing a dielectric layer (CD) above the structured metal layer;
a step of uncovering said first electrodes; and
a step of depositing said stack (EO) of semiconductor organic layers above said first electrodes, and of depositing the second electrode (EL2) on a surface of said stack, said surface being opposite said first electrodes.
